(19) United States
(12) Patent Application Publication
(10) Pub. No.: US 2019/0333938 A1
(43) Pub. Date: Oct. 31, 2019

(54) IN-CELL TOUCH ARRAY SUBSTRATE, DISPLAY PANEL AND MANUFACTURING METHOD THEREOF

(71) Applicant: Wuhan China Star Optoelectronics Technology Co., Ltd., Wuhan (CN)

(72) Inventor: Wei Wang, Wuhan (CN)

(73) Assignee: Wuhan China Star Optoelectronics Technology Co., Ltd., Wuhan (CN)

(21) Appl. No.: 16/313,046

(22) PCT Filed: Sep. 27, 2018
(86) PCT No.: PCT/CN2018/108082

§ 371 Date: Dec. 23, 2018

(30) Foreign Application Priority Data
Apr. 28, 2018 (CN) 201810402217.3

(51) Int. Cl. H01L 27/12; G02F 1/1333; G02F 1/1362; G02F 1/1368; G06F 3/041

(52) U.S. Cl. CPC H01L 27/124; H01L 27/1248; H01L 27/1259; G02F 1/13338; G02F 1/136209; G02F 1/136286; G06F 2203/04103; G06F 3/0412; G02F 2001/13685; G02F 2202/104; G02F 2001/136295; G02F 1/136227; G02F 1/1368

(57) ABSTRACT

The invention provides an in-cell touch array substrate, a display panel and a manufacturing method thereof. The in-cell touch array substrate comprises: a substrate (10); an LTPS TFT array disposed on the substrate (10), comprising a patterned light-shielding layer (11) and a patterned source/drain layer (17); a patterned planarization layer (18) disposed on the LTPS TFT array; a patterned BITO (22) disposed on the planarization layer (18); and a patterned passivation layer (23) on BITO (22); a patterned TITO (24) disposed on the passivation layer (23); and a source/drain layer (17) comprising a first wire (171) connected to the upper BITO (22), the light-shielding layer (11) comprising a second wire (111) as a touch signal line, and the second wire (111) is connected to the upper first wire (171). The invention reduces one mask, reduces film-formation by three, simplifies the process and reduces the cost.

### BACKGROUND OF THE INVENTION

### 1. Field of the Invention

The present invention relates to the field of display techniques, and in particular to an in-cell touch array substrate, display panel and manufacturing method thereof.

### 2. The Related Arts

The touch display panel can be divided according to the structure: the touch circuit covering on the liquid crystal (LC) cell (On-Cell), the touch circuit embedded in the LC cell (In-Cell), and the external type. The in-cell touch display panel has the advantages of low cost and thinness, is favored by major panel manufacturers, and has evolved into the development mainstream of the future touch technology.

Referring to FIG. 1, FIG. 1 is a schematic cross-sectional view of a conventional in-cell touch array substrate. At present, the high-resolution in-cell touch LCD has become the mainstream of low-temperature polysilicon (LTPS) LCD display panels. At present, the in-cell touch adopts the bottom transparent electrode (BITO) 22 as the touch signal electrode, and uses independent metal wire as a touch signal line, and the touch signal line is usually made of a separate third metal layer (M3) 20. Compared with the non-in-cell type, the manufacturing process is necessary to add the first insulating layer 19, the third metal layer 20, and the second insulating layer 21 (IL1 & M3, IL2) three film-formation and two mask processes, which increases costs and decreases yield rate.

The known in-cell touch array substrate mainly comprises: a substrate 10, a low temperature polysilicon thin film transistor (LTPS TFT) array disposed on the substrate 10, a planarization layer 18 disposed on the LTPS TFT array, a first insulating layer 19 disposed on the planarization layer 18, a third metal layer 20 used as a touch signal line, a second insulating layer 21, a bottom transparent electrode 22 used as a touch signal electrode, a passivation layer 23, and a top transparent electrode 24 used as a pixel electrode; the LTPS TFT array mainly comprises a light-shielding layer 11, a buffer layer 12, a polysilicon layer 13, a gate insulating layer 14, a gate layer 15, an interlayer dielectric layer 16, and a source and drain layer 17.

At present, the TFT structure and manufacturing process of the in-cell touch LTPS LCD display panel mainly comprise:

(1) Forming a light-shielding layer (LS) 11: forming a light shielding film→photolithography (photo)→etching→stripping to form a light-shielding layer pattern; forming a light-shielding layer 11 on the substrate 10, the light-shielding layer 11 is generally a metal layer, patterning the light-shielding layer 11 by a mask process to strip the photoresist;

(2) Forming polysilicon layer (P-Si) 13: 3 L film-formation→excimer laser annealing (ELA)→photolithography→dry etching→stripping; a buffer layer 12, such as SiNx/SiOx, is formed on the light-shielding layer 11, and then forming a polysilicon layer 13 on the buffer layer 12, patterning the polysilicon layer 13, and stripping the photoresist;

(3) NCD: photolithography→NCD ion implantation (IMP)→stripping; doping the polysilicon layer 13 to form a channel;

(4) NP: photolithography→NP ion implantation→stripping; heavily doping the polysilicon layer 13 with N-type ions to form source and drain regions on both sides of the NMOS channel;

(5) Forming gate insulating layer 14 & gate layer 15 (GI&Gate): film formation for gate insulating layer 14 & gate layer 15→photolithography→etching→lightly doped drain region (LDD) ion implantation; forming gate insulation layer 14 and gate layer 15, patterning gate layer 15 and gate insulating layer 14, forming a structure of a gate of the TFT and a scan line, and so on, forming a lightly doped drain region by ion implantation;

(6) Pp: photolithography→Pp ion implantation→stripping; heavily doping polysilicon layer 13 with P-type ion to form source and drain regions on both sides of the PMOS channel;

(7) Forming interlayer dielectric layer (ILD) 16: interlayer dielectric layer film-formation→rapid thermal annealing (RTA)→photolithography→dry etching→stripping; forming an interlayer dielectric layer 16, patterned;

(8) Forming source/drain layer (SD) 17: source/drain layer film-formation→lithography→dry etching→stripping; forming a source/drain layer 17, patterning, forming a source/drain and a data line;

(9) Forming planarization layer (PLN) 18: planarization layer photolithography→planarization layer ashing; forming a planarization layer 18, patterning, ashing to remove photoresist;

(10) Forming first insulating layer 19 & third metal layer 20 (IL1 & M3): first insulating layer & third metal layer film-formation→third metal layer photolithography→etching→stripping; forming the first insulating layer 19 and the third a metal layer 20, patterned first insulating layer 19 and third metal layer 20, the third metal layer 20 used as a touch signal line;

(11) Forming second insulating layer (IL2) 21: second insulating layer film-formation→photolithography→dry etching→stripping, forming via between the third metal layer and a bottom transparent electrode (BITO); forming a second insulating layer 21, patterning to form a via between the third metal layer 20 and the BITO 22;

(12) Forming bottom transparent electrode (BITO) 22: BITO film-formation→photolithography→etching→stripping; forming a BITO 22, patterning, BITO 22 used as a touch signal electrode;

(13) Forming passivation layer (PV) 23: passivation layer film-formation→photolithography→dry etching→stripping; forming a passivation layer 23, patterning; in the prior art, when the passivation layer 23 is dry etched to form vias, the etching process is required to penetrate the three-layer films of passivation layer 23/second insulating layer 21/first insulating layer 19, with the high risk of undercut;

(14) Forming top transparent electrode (TITO) 24: TITO film-formation→photolithography→etching→stripping→annealing; forming a TITO 24, patterned.

A total of 14 mask processes are required to complete the process, and the process is complicated and costly.

### SUMMARY OF THE INVENTION

The object of the present invention is to provide an in-cell touch array substrate, display panel and manufacturing method thereof to simplify the process and reduce the cost.

To achieve the above object, the present invention provides an in-cell touch array substrate, which comprises:

a substrate;

a low temperature polysilicon (LTPS) thin film transistor (TFT) array disposed on the substrate, the LTPS TFT array comprising a patterned light-shielding layer and a patterned source/drain layer;

a patterned planarization layer disposed on the LTPS TFT array;

a patterned bottom transparent electrode (B ITO) disposed on the planarization layer;

a patterned passivation layer disposed on the B ITO;

a patterned top transparent electrode (TITO) disposed on the passivation layer;

the source/drain layer comprising a first wire connected to the BITO, the light-shielding layer comprising a second wire used as a touch signal line, and the second wire being connected to the first wire.

Wherein, the LTPS TFT array comprises:

the patterned light-shielding layer disposed on the substrate;

a patterned buffer layer disposed on the substrate and the light-shielding layer;

a patterned polysilicon layer disposed on the buffer layer;

a patterned gate insulating layer disposed on the polysilicon layer and the buffer layer;

a patterned gate layer disposed on the gate insulating layer;

a patterned interlayer dielectric layer disposed on the gate layer;

the patterned source/drain layer disposed on the interlayer dielectric layer.

Wherein, the buffer layer is disposed with a contact hole for connecting the second wire to the first wire.

Wherein, the gate insulating layer is disposed with a via for connecting the second wire to the first wire.

Wherein, the interlayer dielectric layer is disposed with a via for connecting the second wire to the first wire.

Wherein, the planarization layer is disposed with a via for connecting the BITO to the first wire.

Wherein, the planarization layer and the passivation layer are respectively disposed with vias for connecting the TITO to the source/drain layer.

Wherein, the BITO and the TITO are indium tin oxide (ITO) electrodes.

The present invention also provides a display panel comprising the in-cell touch array substrate according to any of the above.

The present invention also provides a manufacturing method of in-cell touch array substrate, comprising the steps of:

forming a light-shielding layer on the substrate, patterning the light-shielding layer, and forming a second wire as a touch signal line;

forming a buffer layer and a polysilicon layer, and patterning the polysilicon layer;

patterning the buffer layer to form a contact hole for connecting a first wire to the second wire;

channel doping the polysilicon layer;

performing N-type ion heavy doping on the polysilicon layer;

forming a gate insulating layer and a gate layer, patterning the gate layer and the gate insulating layer, forming a via in the gate insulating layer for connecting the second wire to the first wire;

heavily doping the polysilicon layer with P-type ion;

forming and patterning an interlayer dielectric layer to form a via for connecting the second wire to the first wire;

forming and patterning a source/drain layer to form the first wire for connection to a bottom transparent electrode (BITO);

forming a planarization layer and patterning to form a via for connecting the BITO to the first wire;

forming a BITO and patterning the BITO;

forming a passivation layer and patterning the passivation layer;

forming a top transparent electrode (TITO) and patterning the TITO.

In summary, the in-cell touch array substrate, display panel and manufacturing method of the invention reduce the number of masks by one, reduce film-formation by three times, simplify process and reduce cost. The reduction of film-formation by three times, simplification of film structure, and avoidance of the three non-metal films of first insulation layer, second insulating layer and passivation layer from directly contacting the conductive film, thereby reduce the probability of film breakage due to poor stress matching, and reduce the high risk of undercutting when dry etching passivation layer to penetrate the three-layer films of passivation layer/second insulating layer/first insulating layer.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic cross-sectional view showing the known in-cell touch array substrate;

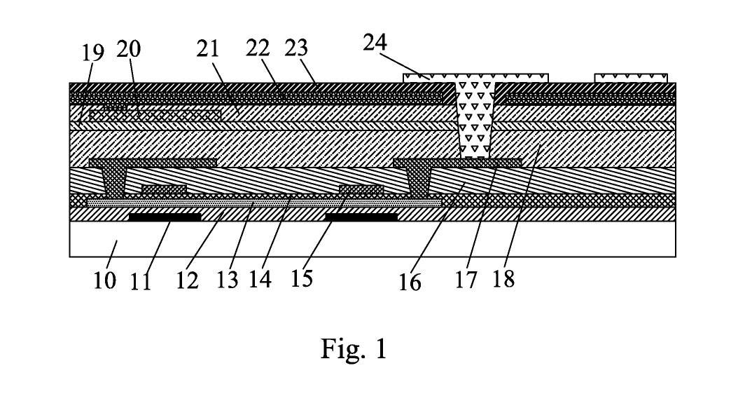

FIG. 2 is a schematic view cross-sectional showing the in-cell touch array substrate of a preferred embodiment of the present invention.

### DETAILED DESCRIPTION OF THE PREFERRED EMBODIMENTS

To further explain the technique means and effect of the present invention, the following uses preferred embodiments and drawings for detailed description.

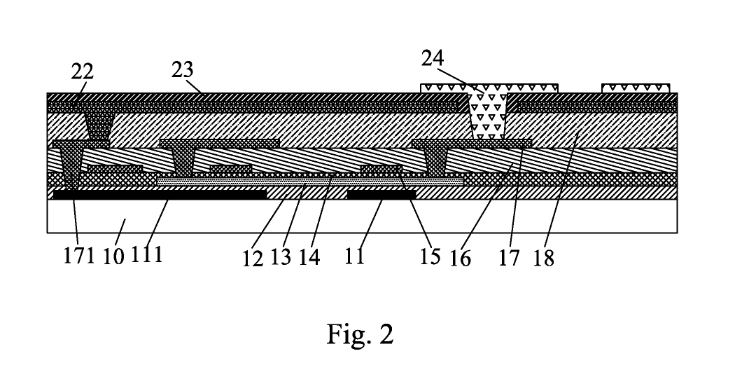

Referring to FIG. 2, FIG. 2 is a schematic view cross-sectional showing the in-cell touch array substrate of a preferred embodiment of the present invention. The in-cell touch array substrate of the preferred embodiment mainly comprises: a substrate 10; a LTPS TFT array disposed on the substrate 10, the LTPS TFT array comprising a patterned light-shielding layer 11 and a patterned source/drain layer 17; a patterned planarization layer 18 disposed on the LTPS TFT array; a patterned bottom transparent electrode (BITO) 22 disposed on the planarization layer 18, used as a touch signal electrode; a patterned passivation layer 23 disposed on the BITO 22; a patterned top transparent electrode (TITO) 24 disposed on the passivation layer 23, used as a pixel electrode.

In the present invention, the metal of source/drain layer 17 of the LTPS TFT array, in addition to forming the source and drain of the TFT and the data line and other structures, also forms a first wire 171 for connection with the BITO 22. The metal of the light-shielding layer 11, in addition to shielding light, also forms a second wire 111 as a touch signal line. The second wire 111 is connected to the first wire 171 such that the second wire 111 and the BITO 22 are electrically connected, one is used as a touch signal line, and the other is used as a touch signal electrode for implementing a touch function.

The structure of the LTPS TFT array is not particularly restricted herein, and is merely illustrated by an exemplar in FIG. 2. The LTPS TFT array mainly comprises: the patterned light-shielding layer 11 disposed on the substrate 10; a patterned buffer layer 12 disposed on the substrate 10 and the light-shielding layer 11; a patterned polysilicon layer 13 disposed on the buffer layer 12; a patterned gate insulating layer 14 disposed on the polysilicon layer 13 and the buffer layer 12; a patterned gate layer 15 disposed on the gate insulating layer 14; a patterned interlayer dielectric layer 16 disposed on the gate layer 15; the patterned source/drain layer 17 disposed on the interlayer dielectric layer 16. The source/drain layer 17 can form a structure, such as source and drain of TFT and a data line.

To connect the second wire 111 to the first wire 171, the BITO 22 is connected to the first wire 171, so that the second wire 111 and the BITO 22 are electrically connected, and the buffer layer 12 may be disposed with a contact hole for connecting the first wire 171 t to the second wire 111. The gate insulating layer 14 is disposed with a via for connecting the second wire 171 to the first wire 111. The interlayer dielectric layer 16 is disposed with a via for connecting the second wire 171 to the first wire 111. The planarization layer 18 is disposed with a via for connecting the BITO 22 to the first wire 171.

Furthermore, the TITO 24 serves as a pixel electrode, and the planarization layer 18 and the passivation layer 23 are respectively disposed with vias for connecting the TITO 24 to the TFT structure of the source/drain layer 17. Both the BITO 22 and the TITO 24 may be indium tin oxide (ITO) electrodes.

The present invention can realize the touch signal line wire design by using the metal of the light-shielding layer directly under the data line, and only need to add a mask process for 3 L buffer layer on the basis of slightly modified the four-layer mask pattern compared with the non-in-cell type. Compared with the known in-cell solution, the present invention can reduce film-formation by 3 times and reduce the number of masks by one, which simplifies the process, reduces the cost, and improves the yield.

According to an embodiment of the in-cell touch array substrate of the present invention, the present invention further provides a display panel comprising the in-cell touch array substrate described above.

The present invention also provides a manufacturing method of in-cell touch array substrate, which can be used to fabricate the in-cell touch array substrate and display panel of the present invention.

A preferred embodiment of the manufacturing method of in-cell touch array substrate comprises the steps of:

(1) forming the light-shielding layer 11: a film for the light-shielding layer 11 is formed→photolithography→etching→stripping to form a touch signal line and a light-shielding layer pattern;

the light-shielding layer 11 is formed on the substrate 10, the light-shielding layer 11 is patterned by a mask, and the photoresist is stripped, and the metal of the light-shielding layer 11 is used for shielding, and a second wire 111 used as a touch signal line is formed;

(2) forming a polysilicon layer 13: 3 L film-formation excimer laser annealing→photolithography→dry etching→stripping;

forming a buffer layer 12 and a polysilicon layer 13, patterning the polysilicon layer 13 to form an island, and stripping the photoresist;

(3) forming a 3 L buffer layer contact hole (Contact Hole): photolithography→dry etching→stripping, forming a 3 L buffer layer 12 contact hole;

adding a mask to pattern the buffer layer 12 to form a contact hole for connecting the second wire 111 to the first wire 171;

(4) NCD: photolithography→NCD ion implantation→stripping;

channel doping of the polysilicon layer 13, for example, channel doping of the NMOS region, and P-type ion light doping treatment on both ends of the PMOS region to form an NMOS channel and a PMOS channel, respectively;

(5) NP: photolithography→NP ion implantation→stripping;

performing N-type ion heavy doping on the polysilicon layer 13; forming source and drain regions respectively located on both sides of the NMOS channel;

(6) forming gate insulating layer 14 & gate layer 15: gate insulating layer 14 & gate layer 15 film-formation→photolithography→etching→lightly doped drain region ion implantation;

forming a gate insulating layer 14 and a gate layer 15, patterning the gate layer 15 and the gate insulating layer 14, forming a TFT gate and a scan line, and forming a via on the gate insulating layer 14 for connecting the second wire 111 to the first wire 171;

(7) Pp: photolithography→Pp ion implantation→stripping;

performing P-type ion heavy doping on the polysilicon layer 13;

forming a source region and a drain region on both sides of the PMOS channel;

(8) forming an interlayer dielectric layer 16: interlayer dielectric layer 16 film-formation→rapid thermal annealing→photolithography→dry etching→stripping;

forming and patterning the interlayer dielectric layer 16 to form a via for connecting the second wire 111 to the first wire 171;

(9) forming a source/drain layer 17: source/drain layer 17 film-formation→photolithography→dry etching→stripping;

forming and patterning the source/drain layer 17, forming a first wire 171 for connection with the BITO 22 in addition to the TFT source/drain and the data line;

(10) forming a planarization layer 18: lithography of the planarization layer 18→ashing of the planarization layer 18;

forming and patterning the planarization layer 18 to form a via for the BITO 22 to connect with the first wire 171; the planarization layer 18 also forms a via for the TFT structure of the TITO 24 connected with the source/drain layer 17.

(11) forming a BITO 22: BITO 22 film-formation photolithography→etching→stripping;

the BITO 22 is formed and patterned, and the bottom BITO 22 can be indium tin oxide (ITO), which can be used as a touch signal electrode;

(12) forming a passivation layer 23: passivation layer 23 film-formation→photolithography→dry etching→stripping;

forming and patterning the passivation layer 23; the passivation layer 23 is disposed with vias for the TFT structure of the TITO 24 connected with the source/drain layer 17;

(13) forming a TITO 24: TITO 24 film-formation→photolithography→etching→stripping→annealing;

the TITO 24 is formed and patterned, and the TITO 24 may be indium tin oxide (TITO), which can be used as a pixel electrode.

The present invention adopts a light-shielding layer for the design of the touch signal line wiring, does not need IL1, M3, IL2 three-layer film-formation, and does not need M3, IL2 two masks, and only needs to add a mask process after the polysilicon layer is completed to form the connection via between the touch electrode and the touch signal line of the light-shielding layer, which can simplify the process and reduce the cost.

Compared with the known manufacturing method of the in-cell touch array substrate, the present invention:

(1) modifying the light-shielding layer mask, the light-shielding layer corresponding to the area immediately below the data line is reserved as the touch signal line, and the connection structure with the upper layer through the vias is added;

(2) adding a mask process after stripping the photoresist of the 3 L polysilicon layer, and forming a via in the 3 L buffer layer for connecting the light-shielding layer touch signal line and the upper source/drain layer;

(3) modifying the interlayer dielectric layer mask to add the interlayer dielectric layer vias for the light-shielding layer touch signal lines and the source/drain layer;

(4) modifying the source/drain layer mask to add the bridge source/drain layer metal connecting the touch signal line and the BITO;

(5) modify the planarization layer mask to add the planarization layer vias for the touch signal lines to connect to the BITO.

In summary, the in-cell touch array substrate, display panel and manufacturing method of the invention reduce the number of masks by one (14 masks→13 masks), reduce film-formation by 3 times, simplify process and reduce cost. The reduction of film-formation by three times (no need of IL1, M3, IL2), simplification of film structure, and avoidance of the three non-metal films of first insulation layer, second insulating layer and passivation layer from directly contacting the conductive film, thereby reduce the probability of film breakage due to poor stress matching, and reduce the high risk of undercutting when dry etching passivation layer to penetrate the three-layer films of passivation layer/second insulating layer/first insulating layer.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claim of the present invention.

What is claimed is:

1. An in-cell touch array substrate, comprising:
a substrate;
a low temperature polysilicon (LTPS) thin film transistor (TFT) array disposed on the substrate, the LTPS TFT array comprising a patterned light-shielding layer and a patterned source/drain layer;
a patterned planarization layer disposed on the LTPS TFT array;
a patterned bottom transparent electrode (BITO) disposed on the planarization layer;
a patterned passivation layer disposed on the B ITO;
a patterned top transparent electrode (TITO) disposed on the passivation layer;
the source/drain layer comprising a first wire connected to the BITO, the light-shielding layer comprising a second wire used as a touch signal line, and the second wire being connected to the first wire.

2. The in-cell touch array substrate as claimed in claim 1, wherein the LTPS TFT array comprises:
the patterned light-shielding layer disposed on the substrate;
a patterned buffer layer disposed on the substrate and the light-shielding layer;
a patterned polysilicon layer disposed on the buffer layer;
a patterned gate insulating layer disposed on the polysilicon layer and the buffer layer;
a patterned gate layer disposed on the gate insulating layer;
a patterned interlayer dielectric layer disposed on the gate layer;
the patterned source/drain layer disposed on the interlayer dielectric layer.

3. The in-cell touch array substrate as claimed in claim 2, wherein the buffer layer is disposed with a contact hole for connecting the second wire to the first wire.

4. The in-cell touch array substrate as claimed in claim 2, wherein the gate insulating layer is disposed with a via for connecting the second wire to the first wire.

5. The in-cell touch array substrate as claimed in claim 2, wherein the interlayer dielectric layer is disposed with a via for connecting the second wire to the first wire.

6. The in-cell touch array substrate as claimed in claim 1, wherein the planarization layer is disposed with a via for connecting the BITO to the first wire.

7. The in-cell touch array substrate as claimed in claim 1, wherein the planarization layer and the passivation layer are respectively disposed with vias for connecting the TITO to the source/drain layer.

8. The in-cell touch array substrate as claimed in claim 1, wherein the BITO and the TITO are indium tin oxide (ITO) electrodes.

9. A display panel, comprising an in-cell touch array substrate as claimed in claim 1.

10. A manufacturing method of in-cell touch array substrate, comprising:
forming a light-shielding layer on the substrate, patterning the light-shielding layer, and forming a second wire as a touch signal line;
forming a buffer layer and a polysilicon layer, and patterning the polysilicon layer;
patterning the buffer layer to form a contact hole for connecting a first wire to the second wire;
channel doping the polysilicon layer;
performing N-type ion heavy doping on the polysilicon layer;
forming a gate insulating layer and a gate layer, patterning the gate layer and the gate insulating layer, forming a via in the gate insulating layer for connecting the second wire to the first wire;
heavily doping the polysilicon layer with P-type ion;
forming and patterning an interlayer dielectric layer to form a via for connecting the second wire to the first wire;
forming and patterning a source/drain layer to form the first wire for connection to a bottom transparent electrode (BITO);
forming a planarization layer and patterning to form a via for connecting the BITO to the first wire;
forming a BITO and patterning the BITO;
forming a passivation layer and patterning the passivation layer;
forming a top transparent electrode (TITO) and patterning the TITO.
